(19) United States
(12) Patent Application Publication
(10) Pub. No.: US 2007/0145367 A1
(43) Pub. Date: Jun. 28, 2007

(54) Three-dimensional integrated circuit structure

(75) Inventors: Hai-Ching Chen, Hsinchu City (TW); Harold C.H. Hsiung, Taipei (TW); Henry Lo, Hsinchu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/319,922

(22) Filed: Dec. 27, 2005

(51) Int. Cl. H01L 29/04

(52) U.S. Cl. 257/49

(57) ABSTRACT

The preferred embodiments of the present invention provide a three-dimensional (3D) semiconductor structure and a method of forming the same. The 3D semiconductor structure includes a first substrate bonded to a second substrate. The first substrate includes substantially all NMOS devices. The second substrate includes substantially all PMOS devices. The substrates can be bonded face-to-face, face-to-back, or back-to-back. The method includes providing a first substrate and a second substrate, forming a first circuit comprising at least one NMOS device on the first substrate, wherein the first substrate includes substantially no PMOS devices, forming a second circuit comprising at least one PMOS device on the second substrate, wherein the second substrate includes substantially no NMOS devices, and bonding the first and second substrates after forming the first and second circuits.

### TECHNICAL FIELD

This invention relates generally to integrated circuits, and more particularly to three-dimensional integrated circuits and manufacturing processes for forming the same.

### BACKGROUND

Since the invention of the integrated circuit, the semiconductor industry has experienced continued rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area. Additional improvement has come from increases in wafer size.

These integration improvements are essentially two-dimensional (2D) in nature, in that the volume occupied by the integrated components is essentially on the surface of the semiconductor wafer. Although dramatic improvement in lithography has resulted in considerable improvement in 2D integrated circuit formation, there are physical limits to the density that can be achieved in two dimensions. One of these limits is the minimum size needed to make these components. Also, when more devices are put into one chip, more complex designs are required.

An additional limit comes from the significant increase in the number and length of interconnections between devices as the number of devices increases. When the number and length of interconnections increase, both circuit RC delay and power consumption increase.

Three-dimensional (3D) integrated circuits (ICs) are therefore created to resolve the above-discussed limitations. In typical 3D integrated circuit formation processes, two substrates, each including an integrated circuit, are formed. The substrates are then bonded with the devices aligned. Deep vias are then formed to interconnect devices on the first and second substrates.

Much higher device density has been achieved using 3D IC technology, and up to 6 layers of substrates have been bonded. As a result, the total wire length is significantly reduced. Compared to 2D technology, experiment results have revealed that if two layers are bonded, the total wire length can be reduced by up to about 28 percent. If five layers are bonded, the total wire length can be reduced by up to about 51 percent. The number of vias is also reduced. It has been found that if two layers are bonded, the total via number can be reduced by up to about 7 percent, and if five layers are bonded, the total via number can be reduced by up to about 17 percent. Therefore, 3D technology has the potential of being the mainstream technology of the next generation.

Being relatively new, 3D IC technology is far from being fully researched, and its potential needs to be further explored. The preferred embodiments of the present invention provide a novel method of fabricating 3D ICs with less cost and complexity over conventional 3D fabrication methods.

### SUMMARY OF THE INVENTION

The preferred embodiments of the present invention provide a three-dimensional (3D) semiconductor structure and a method of forming the same.

In accordance with one aspect of the present invention, the 3D semiconductor structure includes a first substrate bonded to a second substrate. The first substrate includes substantially all NMOS devices. The second substrate includes substantially all PMOS devices. In one embodiment of the present invention, contact pads are pre-formed on the first and second substrates, and bonded using a conductive material. In other embodiments, the first and second substrates are bonded using an electrically insulating material, and vias are formed, interconnecting devices on the first and second substrates.

In accordance with another aspect of the present invention, the first substrate includes silicon having a crystal orientation of (100), and the second substrate includes silicon having a crystal orientation of (110). Preferably, the first substrate is lightly doped with a p-type impurity, and the second substrate is lightly doped with an n-type impurity. The first and second substrates may be bonded face-to-face, face-to-back, or back-to-back.

In accordance with yet another aspect of the present invention, the method of forming the 3D semiconductor structure includes providing a first and a second substrate, forming a first circuit including substantially all NMOS devices on the first substrate, forming a second circuit including substantially all PMOS devices on the second substrate, and bonding the first and second substrates. The bonding of the first and second substrates includes face-to-face bonding, face-to-back bonding, and back-to-back bonding.

In accordance with yet another aspect of the present invention, the method further includes pre-forming contact pads on the surface of the first and second substrates, and bonding the contact pads using a conductive material.

In accordance with yet another aspect of the present invention, the first and second substrates are bonded by an electrically insulating material, and the method further includes forming vias interconnecting the devices on the first and second substrates.

In the preferred embodiments of the present invention, PMOS and NMOS devices are fabricated on separate substrates, so that the fabrication processes are simplified. Since the materials and fabrication processes can be customized with respect to the types of MOS devices, the performance of the integrated circuit is improved. Circuit RC delay is reduced, and power consumption is also reduced.

### BRIEF DESCRIPTION OF THE DRAWINGS

For a more complete understanding of the present invention, and the advantages reference is now made to the following descriptions taken in conjunction with the accompanying drawings, in which:

FIGS. 1 and 2 illustrate schematic cross-sectional views of a preferred embodiment of th present invention, wherein a substrate comprising NMOS devices and a substrate comprising PMOS devices are formed, and wherein contact pads are pre-formed and bonded using a conductive material;

FIGS. 3 through 5B illustrate schematic cross-sectional views of another preferred embodiment of the present invention, wherein two substrates are bonded using an electrically insulating material, and devices are interconnected using vias;

FIG. 6 illustrates three substrates bonded;

FIGS. 7 through 9 illustrate face-to-back bonding of two substrates; and

FIGS. 10 and 11 illustrate cross-sectional views of two substrates bonded back-to-back.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

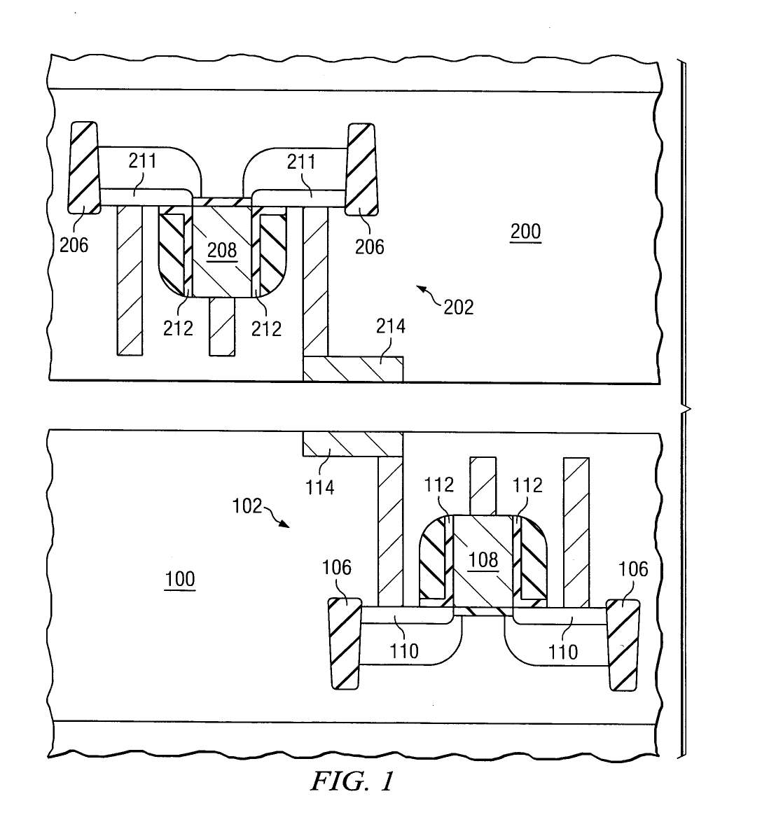

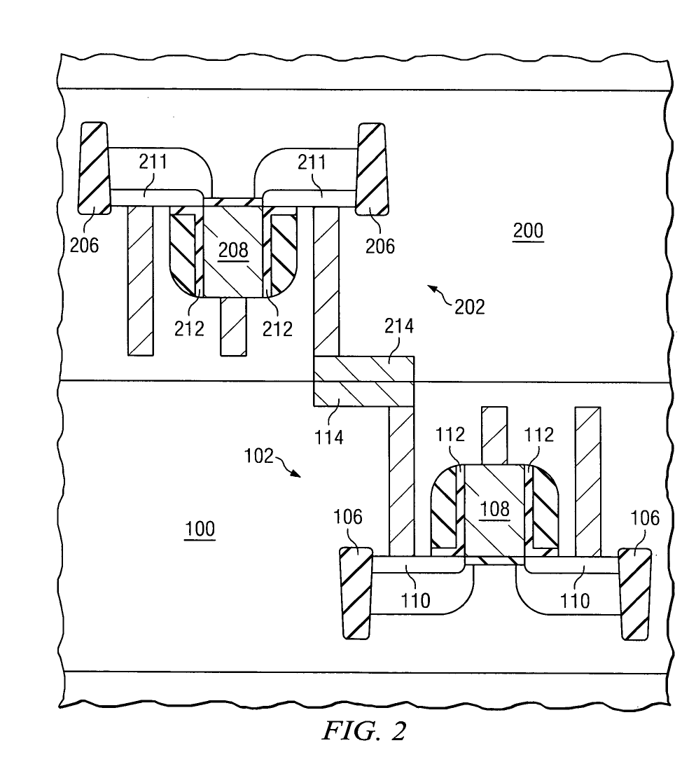

FIGS. 1 and 2 illustrate schematic cross-sectional views of a preferred embodiment of the present invention, wherein contact pads are pre-formed prior to bonding. In FIG. 1, a first substrate 100 and a second substrate 200 are provided. While in an ideal situation no PMOS devices are formed on substrate 100, in some embodiments, a limited number of PMOS devices might be formed on the substrate 100 to satisfy particular circuit requirements. Preferably, the first and second substrates are formed of different materials that are beneficial for NMOS and PMOS devices, respectively. In the preferred embodiment, the first substrate 100 comprises silicon lightly doped with p-type impurities, and has a preferred crystal orientation of (100). The second substrate 200 comprises silicon lightly doped with n-type impurities, and has a preferred crystal orientation of (110). In alternative embodiments, the first and second substrates are formed of other materials, such as silicon, SiGe, germanium, or combinations thereof, and the first and second substrates preferably comprise different materials. For example, the first substrate 100 is formed of silicon, and the second substrate 200 is formed of silicon germanium epitaxially grown on silicon. In yet other embodiments, each of the substrates 100 and 200 may comprise bulk semiconductor, silicon on insulator, silicon germanium on insulator, strained silicon on insulator, or other materials and structures that are suitable for respective NMOS and PMOS devices. For example, the substrate 100 may be formed of a silicon body having a crystal orientation of (150) on a 110 insulator layer, or a strained silicon body on a graded Siₓ,Ge₁₋ₓ layer. Preferably, there is no SiGe grown in the source/drain regions on the substrate 100. While the substrate 200 may be formed of a silicon body having a crystal orientation of (200) on a 110 insulator, or a strained silicon body on a graded Si_{y}Ge_{1-y} layer, wherein x and y are between 0 and 1, and preferably have different values. Preferably, SiGe regions are epitaxially grown on the source/drain regions on the substrate 200.

Since an NMOS device has better performance if formed on a silicon substrate in the (100) direction, the substrate 100 preferably includes substantially all NMOS devices. FIG. 1 illustrates an exemplary core circuit NMOS device 102 on the substrate 100. Since there are no PMOS devices on the substrate 100, the device formation processes can be adjusted according to the requirements of the NMOS devices. For example, the following formation parameters can be applied to the NMOS formation processes:

Depth of shallow trench isolation (STI) regions 106: ˜3500 Å

Thickness of the gate electrode 108: ˜900 Å

Thickness of the silicide 110: ˜300 Å

Thickness of the liner 112: ˜50-300 Å

Preferred stress in the channel region: tensile.

After the formation of the device 102, the substrate is preferably annealed using rapid thermal annealing at about 1100° C.

FIG. 1 also illustrates an exemplary core circuit PMOS device 202 on a substrate 200, in an upside down position. To achieve optimum performance, the substrate 200 includes substantially all PMOS devices. Again, while it is preferred that no NMOS devices are formed, some embodiments might require a limited number of NMOS devices for particular circuit needs. Further adjustment can be made by applying the following parameters to the PMOS formation processes:

Depth of shallow trench isolation (STI) regions 206: ˜3000 Å

Thickness of the gate electrode 208: ˜800 Å

Thickness of the liner 212: ˜150-500 Å

Preferred stress in the channel region: compressive.

After the formation of the device 202, the substrate is preferably spike annealed at about 1050° C. Additionally, to increase the compressive strain in the channel region, epitaxial SiGe regions 211 with a preferred thickness of about 400 Å are preferably formed in the source/drain silicon regions. It is to be noted that the NMOS device and PMOS device formation parameters are used for explaining the preferred embodiments of the present invention, and one skilled in the art will realize that different parameters may be applied with respect to design requirements.

Each of the substrates 100 and 200 can include more devices, such as capacitors, resistors, etc. Contact pads 114 and 214, which are connected to the contact plugs of the respective devices 102 and 202, are preferably formed on the respective substrates and externally exposed. Contact pads (not shown) for other sources/drains and gate electrodes will also be formed if connections are to be made to devices on the other substrate.

FIG. 2 illustrates the substrates 100 and 200 joined by bonding. The substrates are aligned so that the contact pad 114 on the first substrate 100 is bonded to the contact pad 214 on the second substrate 200. The contact pads 114 and 214 can be bonded using a conductive material, such as copper or tantalum. In an exemplary bonding process, copper bonding is performed at 350° C. for about 30 minutes, aligning the substrates, putting the substrates together and applying pressure, cooling down, and annealing at 350° C. for about 60 minutes. Copper dummy patterns can be used as contact pads 114 and 214 to improve bonding strength. The advantageous features of using copper dummy patterns as contact pads include distributing bonding force applied on the bonding area during the bonding process and minimizing impact on the copper CMP process since large size/pitch Cu studs cause process difficulties. Through the interconnection between the contacts pads 114 and 214, the devices 102 and 202 are interconnected.

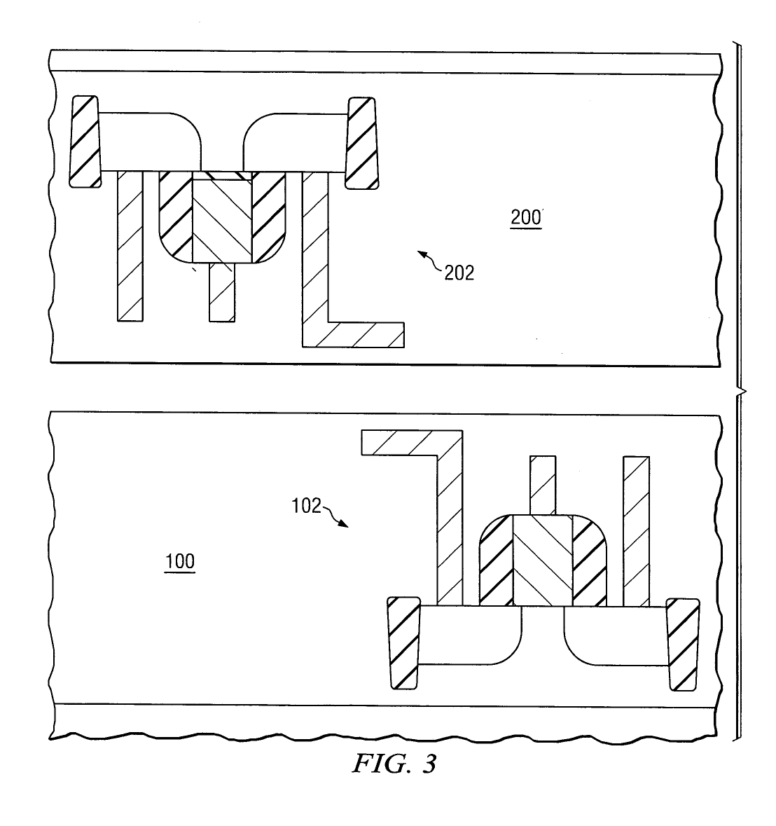

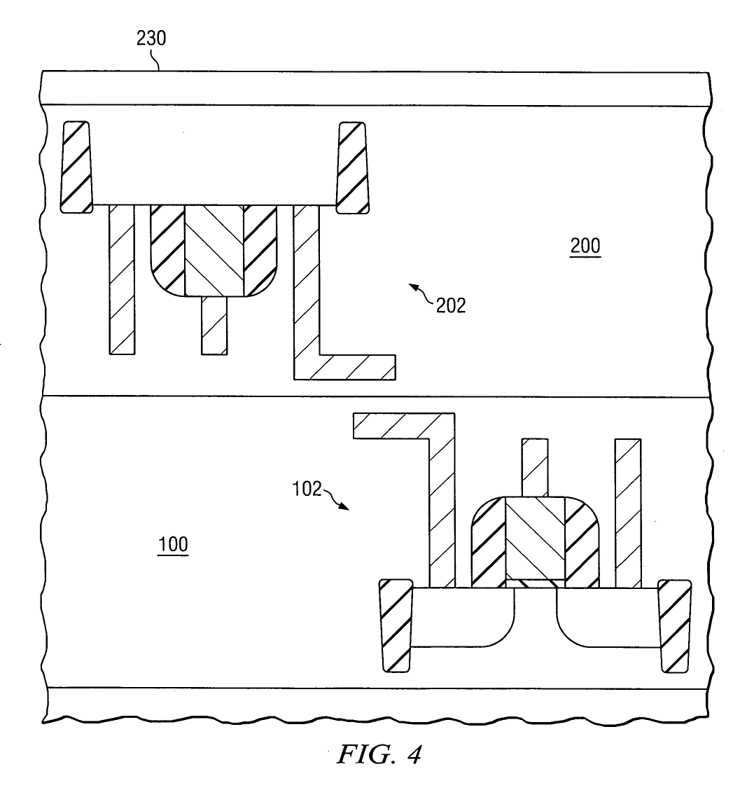

The substrates 100 and 200 described in previous paragraphs may be bonded using other methods, which are illustrated in FIGS. 3 through 11. FIGS. 3 through 6 illustrate schematic cross-sectional views of another preferred embodiment of the present invention, wherein no contact pads are formed prior to bonding. The first substrate 100 and second substrate 200 are illustrated in FIG. 3. For simplicity, the details of the devices 102 and 202 are omitted. The substrates 100 and 200 are bonded, as illustrated in FIG. 4, preferably using an electrically insulating adhesive. In the preferred embodiment, the electrical insulating adhesive is a polymer, such as benzocyclobutene (BCB) cyclotene, or PI2610 polymide HTR3 manufactured by Dupont, etc. Preferably, the bonding process includes pre-cleaning the substrates, applying an adhesive to at least one of the substrates 100 and 200, pre-curing the adhesive to evaporate the solvents, joining and aligning the substrates, and curing the adhesive.

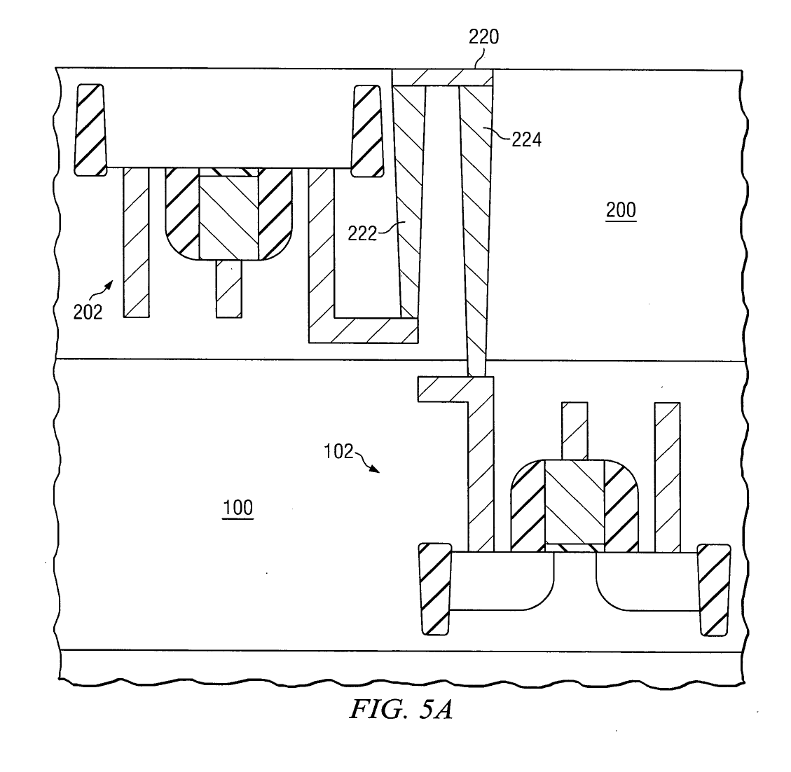

One of the substrates, such as the substrate 200, is preferably thinned by removing a portion 230. In the preferred embodiment, as shown in FIG. 5A, a contact pad 220 and vias 222 and 224 are formed, interconnecting the devices 102 and 202. In other embodiments, vias 220 and 222 are connected by a third via instead of the contact pad 220. In yet other embodiments, as shown in FIG. 5B, one contact via 226 is formed, electrically coupling devices 102 and 202. However, the formation of the structure in FIG. 5B requires high accuracy so that contact via 226 is not too close to or too far from any of the devices 102 and 202.

When forming the first substrate 100 or second substrate 200, the substrate is preferably formed on a wafer, which preferably comprises multiple substrates (or chips) having the same design. In the preferred embodiment of the present invention, a bonding is performed at the wafer level, and a first wafer comprising the substrate 100 is bonded to a second wafer comprising the substrate 200. The chips, each including a substrate 100 and a substrate 200, are then cut from the bonded wafer. Since the entire first or second substrate wafer comprises NMOS or PMOS devices only, the manufacturing processes are simplified. For example, when forming a wafer containing the first substrate 100, there is no need to mask PMOS devices, as is typically required in conventional fabrication processes. In other embodiments, the bonding of the substrates 100 and 200 are performed at the chip level, and a first chip comprising substantially all NMOS devices and a second chip comprising substantially all PMOS devices are cut from the respective wafers, and then bonded.

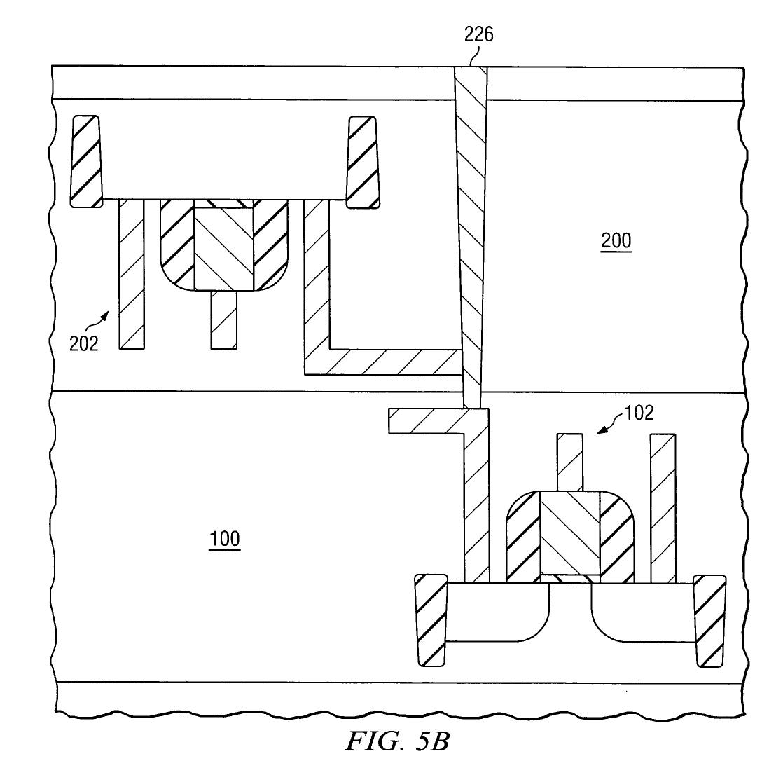

More substrates can be bonded to the previously discussed 3D structure. FIG. 6 illustrates an example of bonding a third substrate 300 to the substrate 200. In the preferred embodiment, the substrate 300 includes input/output (IO) devices. As known in the art, IO devices have different characteristics from core devices, and thus are formed using different fabrication processes. For example, gate dielectrics of IO MOS devices are typically thicker. More preferably, the substrate 300 includes IO PMOS devices, but no IO NMOS devices, or IO NMOS devices, but no IO PMOS devices. In other embodiments, the substrate 300 comprises core PMOS devices only, or core NMOS devices only. FIG. 6 illustrates a structure in which no contact pads are formed prior to bonding, and the substrate 300 is bonded to the substrate 200 through a contact pad 314 and vias 316 and 318. In alternative embodiments, contact pads can be formed prior to bonding, and the substrates 100, 200, and 300 can be joined by bonding the contact pads using a conductive material.

When more than two substrates are to be bonded, the bonding scheme will be chosen such that the total length of the interconnections between the substrates is less, so that the overall performance of the bonded substrates is high. For example, four substrates are to be bonded, which includes a substrate A comprising substantially all core NMOS devices, a substrate B comprising substantially all core NMOS devices, a substrate C comprising substantially all IO NMOS devices, and a substrate D comprising substantially all IO PMOS devices. Substrates A and B are preferably bonded next to each other, since more interconnections exist between substrates A and B. If substrates C and D have balanced numbers of n-type and p-type devices, substrates C and D are preferably bonded together, and the bonded substrates C and D can be bonded to either side of the bonded substrates A and B. However, if the IO circuit is n-type dominant, and the substrate C has a significantly greater number of NMOS devices than the number of PMOS devices in the substrate D, the substrate C is preferably bonded next to the substrate A or B, and the substrate D can be bonded either next to substrate C or one of the substrates A and B.

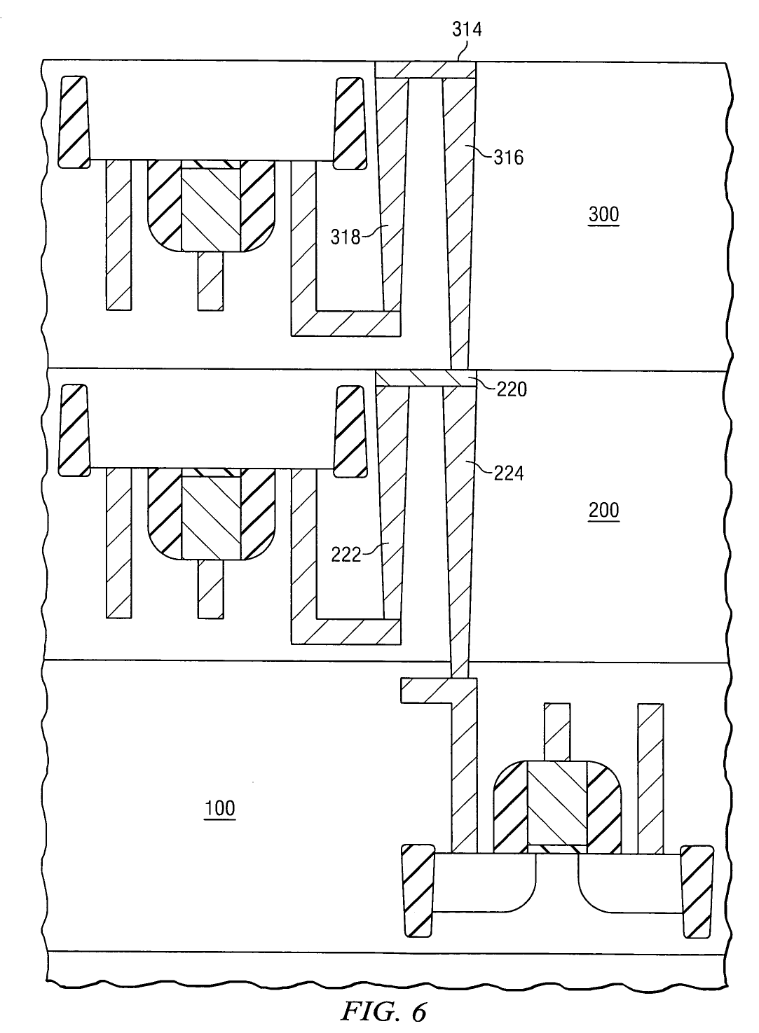

The previously discussed preferred embodiments of the present invention illustrate face-to-face bondings of the substrates. The substrates 100 and 200 can also be bonded face-to-back, as illustrated in FIGS. 7 through 9. In FIG. 7, a handle wafer 230, preferably formed of glass, is attached to one of the substrates, such as the substrate 200. The substrate 200 is then thinned by removing a portion 232 using etching or other known methods.

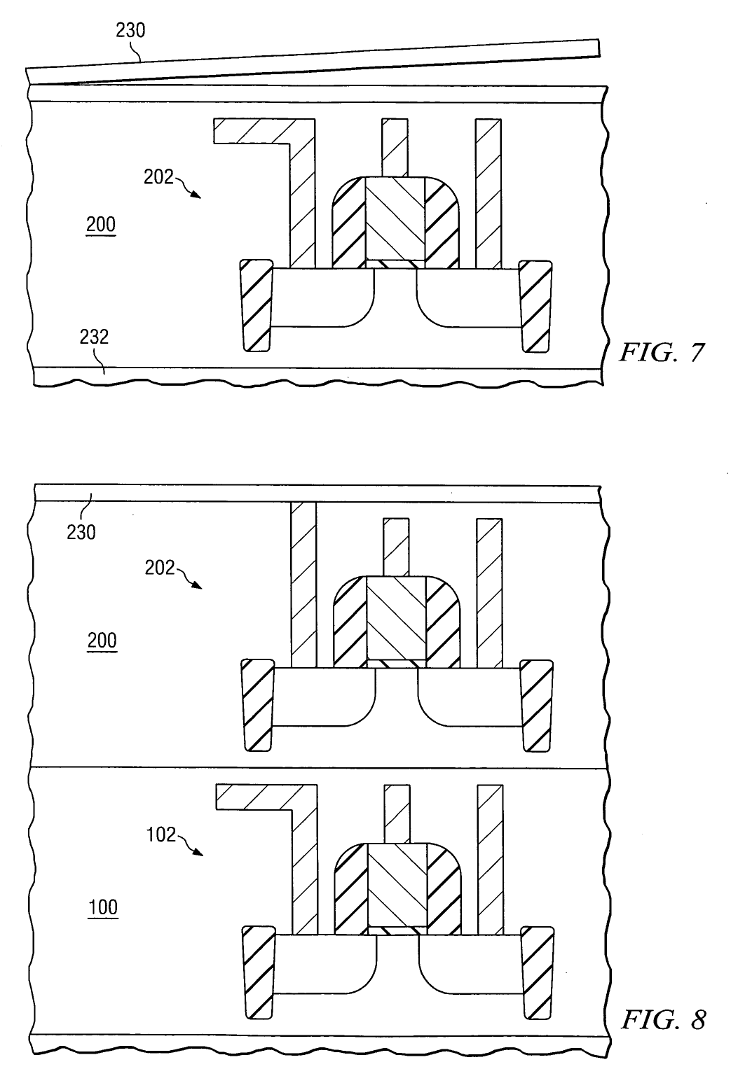

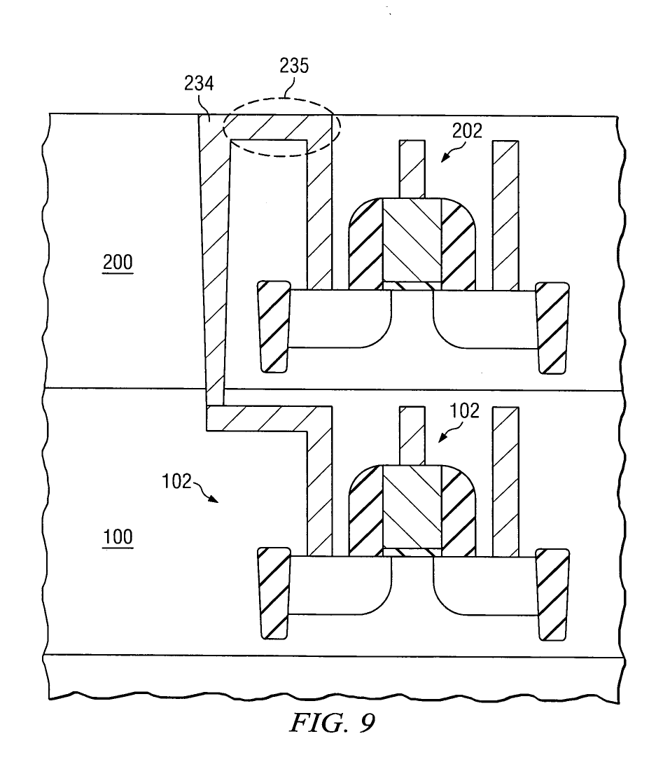

Referring to FIG. 8, the substrates 100 and 200 are bonded face-to-back by an electrically insulating adhesive. The handle wafer 230 is then removed, preferably using laser ablation or etching. Via 234 is then formed to interconnect devices 102 and 202, and the resulting structure is shown in FIG. 9. A horizontal leg 235 may be formed together with the via 234 using a dual damascene process.

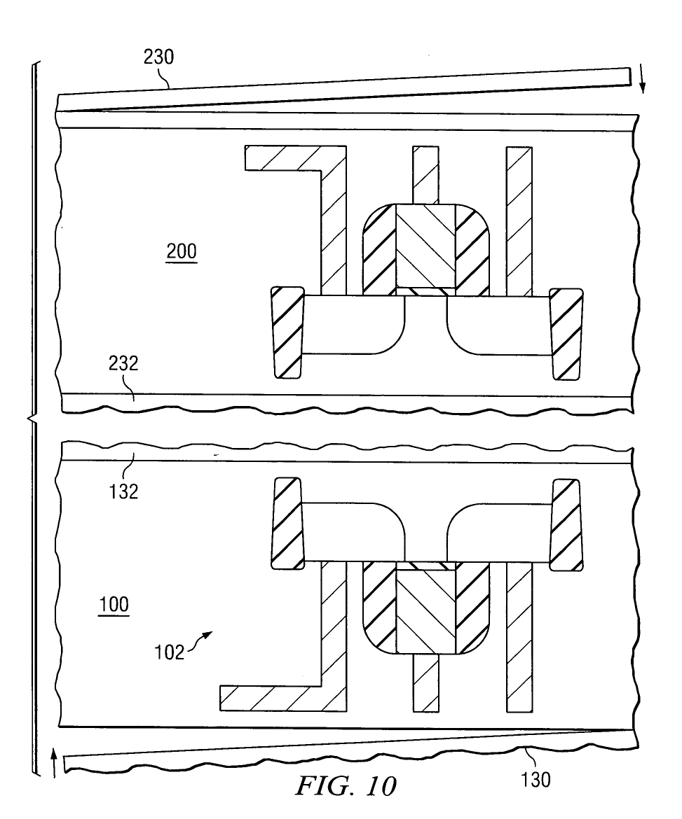

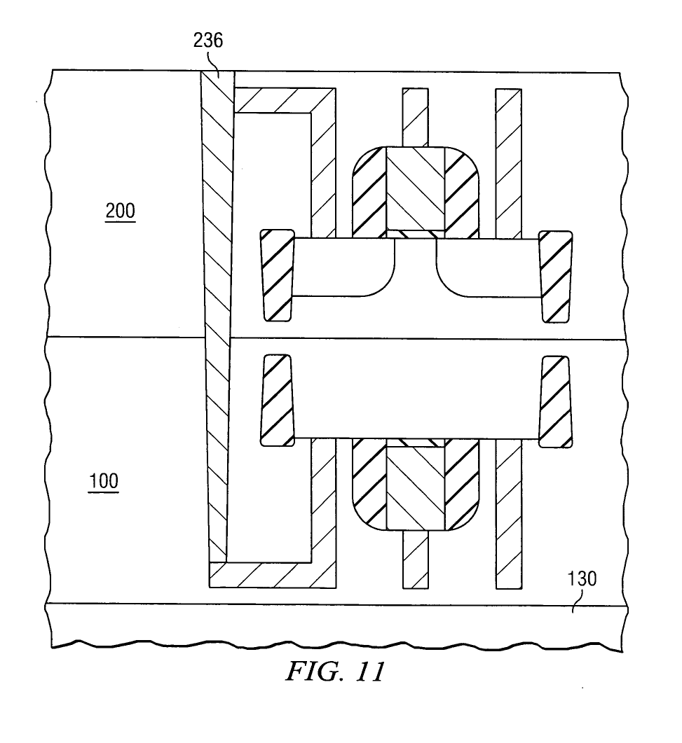

FIGS. 10 and 11 illustrate a back-to-back bonding of the substrates 100 and 200. Referring to FIG. 10, a first handle wafer 130 is attached to the face of the substrate 100, and a second handle wafer 230 is attached to the face of the substrate 200. Respective portions 132 and 232 of the substrates 100 and 200 are then removed from the backs of the respective substrates. FIG. 11 illustrates the bonding of the substrates 100 and 200. One of the handle wafers, such as handle wafer 230, is then removed, and the devices 102 and 202 are interconnected by a via 236. The bonded substrates can be further bonded to other substrates. After further bonding, the handle wafer 130 can be removed.

By using the preferred embodiments of the present invention, manufacturing processes are simplified, as each substrate contains NMOS or PMOS devices only. The performance of the integrated circuit is improved due to customized fabrication processes with respect to the type of MOS devices. With the 3D structure, circuit RC delay is reduced, and power consumption is reduced.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A three-dimensional (3D) semiconductor structure comprising:
a first chip bonded to a second chip, wherein the first chip comprises substantially all NMOS devices, and wherein the second chip comprises substantially all PMOS devices.

2. The 3D semiconductor structure of claim 1 further comprising at least one via extending from the first chip to the second chip, electrically coupling a first device on the first chip and a second device on the second chip.

3. The 3D semiconductor structure of claim 1 wherein the first and second chips comprise substantially different materials.

4. The 3D semiconductor structure of claim 1 wherein the first chip comprises silicon having a crystal orientation of (100), and the second chip comprises silicon having a crystal orientation of (110).

5. The 3D semiconductor structure of claim 1 wherein the first chip is doped with a p-type impurity, and the second chip is doped with an n-type impurity.

6. The 3D semiconductor structure of claim 1 further comprising a first IO circuit on the first chip, and a second IO circuit on the second chip.

7. The 3D semiconductor structure of claim 1 wherein the first and the second chips are bonded face-to-face.

8. The 3D semiconductor structure of claim 1 wherein the first and the second chips are bonded face-to-back.

9. The 3D semiconductor structure of claim 1 wherein the first and the second chips are bonded back-to-back.

10. The 3D semiconductor structure of claim 1 wherein devices on the first chip and devices on the second chip are bonded through contact pads on surfaces of the respective first chip and second chip.

11. The 3D semiconductor structure of claim 10 wherein the contact pads are formed of dummy copper.

12. The 3D semiconductor structure of claim 1 wherein surfaces of the first chip and the second chip are substantially free of contact pads.

13. A three dimensional (3D) semiconductor structure comprising:
a first layer comprising a plurality of NMOS devices, but no PMOS devices; and
a second layer comprising a plurality of PMOS devices, but no NMOS devices, wherein at least one NMOS device in the first layer is electrically coupled to at least one PMOS device in the second layer, and wherein the first and second layers are bonded after the NMOS devices and PMOS devices are formed in the respective layers.

14. The 3D semiconductor structure of claim 13 wherein the first and the second layers are bonded by conductive interconnections.

15. The 3D semiconductor structure of claim 13 wherein the first and the second layers comprise substantially different materials.

16. The 3D semiconductor structure of claim 13 wherein an interface between the first and the second layers comprise contact pads connecting devices in the first layer and the second layer.

17. The 3D semiconductor structure of claim 16 wherein the contact pads are formed of dummy copper.

18. The 3D semiconductor structure of claim 13 wherein an interface between the first and the second layers is substantially free of contact pads connecting devices in the first layer and the second layer.

19. A three-dimensional (3D) semiconductor structure comprising:
a first wafer having at least one characteristic optimized for NMOS device performance;
a second wafer having at least one characteristic optimized for NMOS device performance;
wherein the first wafer is bonded to the second wafer; and
wherein the first wafer comprises substantially all NMOS devices, and wherein the second wafer comprises substantially all PMOS devices.

20. The 3D semiconductor structure of claim 19 wherein the first wafer comprises silicon having a crystal orientation of (100), and the second wafer comprises silicon having a crystal orientation of (110).

21. The 3D semiconductor structure of claim 19 wherein the first wafer is doped with a p-type impurity, and the second wafer is doped with an n-type impurity.
